(19) United States
(12) Patent Application Publication
(10) Pub. No.: US 2012/0134505 A1
(43) Pub. Date: May 31, 2012

(54) METHOD FOR THE OPERATION OF A HEARING DEVICE AND HEARING DEVICE WITH A LENGTHENING OF FRICATIVES

(75) Inventors: ULRICH GIESE, FUERTH (DE); SEBASTIAN PAPE, ERLANGEN (DE); MAJA SERMAN, ERLANGEN-BUCKENHOF (DE)

(73) Assignee: SIEMENS MEDICAL INSTRUMENTS PTE. LTD., SINGAPORE (SG)

(21) Appl. No.: 13/303,426

(22) Filed: Nov. 23, 2011

(30) Foreign Application Priority Data
Nov. 25, 2010 (DE) 10 2010 061 945.0

(51) Int. Cl. H03G 3/00; H04R 25/00

(52) U.S. Cl. 381/63; 381/312

(57) ABSTRACT

A method operates a hearing device and an associated hearing device has at least one microphone for recording an ambient sound and an earpiece emitting an output sound. A fricative of the ambient sound is reproduced in a temporally lengthened form by the hearing device in the output sound. Speech intelligibility for the hearing-impaired can be improved by the lengthening of fricatives.

### CROSS-REFERENCE TO RELATED APPLICATION

This application claims the priority, under 35 U.S.C. §119, of German application DE 10 2010 061 945.0, filed Nov. 25, 2010; the prior application is herewith incorporated by reference in its entirety.

### BACKGROUND OF THE INVENTION

### Field of the Invention

The invention relates to a method for operating a hearing device and an associated hearing device, whereby fricatives of an input sound signal are reproduced in an output sound signal in a temporally lengthened form.

As their major components, hearing devices principally have an input converter, an amplifier and an output converter. The input converter is as a rule a sound receiver, for example a microphone, and/or an electromagnetic receiver, for example an induction coil. The output converter is usually realized as an electroacoustic converter, for example a miniature loudspeaker, or as an electromechanical converter, e.g. bone conductor. The amplifier is generally integrated into a signal processing unit.

The structural principle is represented in FIG. 1, using a behind-the-ear hearing device 1 as an example. Two microphones 3 for recording sound from the environment are generally built into a hearing device housing 2 to be worn behind the ear. Embodied in the hearing device housing 2 above the microphones 3 are microphone openings 7. Through these sound openings 7 the sound can reach the microphones 3 in an interior of the hearing device housing. A signal processing unit 4, which is likewise integrated into the hearing device housing 2, processes the microphone signals and amplifies them. The output signal from the signal processing unit 4 is transferred to a loudspeaker or earpiece 5, which outputs an acoustic signal. Where appropriate, the sound is conveyed to the eardrum of the hearing device wearer via a non-illustrated sound tube, which is fixed in the auditory canal with an otoplastic. The power supply for the hearing device 1 and in particular for the signal processing unit 4 is provided by a battery 6 likewise integrated into the hearing device housing 2.

A fricative, also known as a spirant or strident sound, is a consonant named for its mode of articulation, for example f, s, v, z. Upon its articulation a constriction is formed, which causes a swirling of the emerging air and creates the fricative. Fricatives can be unvoiced or voiced. A large subset of the fricatives is made up of the sibilant sounds, which are formed in the forward area of the mouth, and are characterized by an audible whistling or hissing.

By far the most important task that a hearing device must fulfill is to support interpersonal communication through the sustained improvement of speech intelligibility. In noisy environments, in the case of continuous disruptive sounds or in situations in which a number of people are speaking at the same time, this problem is of particular significance.

Where there is background noise, even those with normal hearing frequently experience difficulties in picking out and understanding the voices of their interlocutors, and understanding what they wish to impart. If the level of background noise is 6 decibels louder than the spoken word, even persons with good hearing hear only some 40 percent of the words spoken. In such situations people with hearing loss can hear almost nothing else.

### SUMMARY OF THE INVENTION

It is accordingly an object of the invention to provide a method for the operation of a hearing device and a hearing device with a lengthening of fricatives which overcome the above-mentioned disadvantages of the prior art methods and devices of this general type, which improves speech intelligibility on a sustainable basis.

The invention claims a method for the operation of a hearing device with at least one microphone recording an ambient sound and an earpiece emitting an output sound. Here, a fricative from the ambient sound is reproduced in a temporally lengthened form in the output sound by the hearing device. By the lengthening of fricatives, speech intelligibility for the hearing-impaired can be improved.

In a development, the temporal lengthening can contain a reverberation of the fricative.

In a further embodiment, the temporal lengthening can contain an n-fold multiplication of the fricative, whereby n is ∈R and n>1.

Furthermore, the method can contain the steps of: identification of a fricative signal in a microphone signal, and mixing of an earpiece input signal with the fricative signal or a changed fricative signal.

The invention also claims a hearing device with at least one microphone recording an ambient sound and with an earpiece emitting an output sound. The hearing device is embodied in such a way that it identifies a fricative in a microphone signal and reproduces the fricative in temporally lengthened form in an earpiece input signal.

In a development, the hearing device can contain an identifying unit, which identifies a fricative in a microphone signal, a change unit, which changes the identified fricative, and an adder, which adds the changed fricative to the earpiece input signal.

Other features which are considered as characteristic for the invention are set forth in the appended claims.

Although the invention is illustrated and described herein as embodied in a method for the operation of a hearing device and a hearing device with a lengthening of fricatives, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is an illustration of a behind-the-ear hearing device according to the prior art;

FIG. 2 is a flow chart of a method for operating a hearing device with a lengthening of fricatives according to the invention; and

FIG. 3 is a block diagram of the hearing device with a lengthening of fricatives according to the invention.

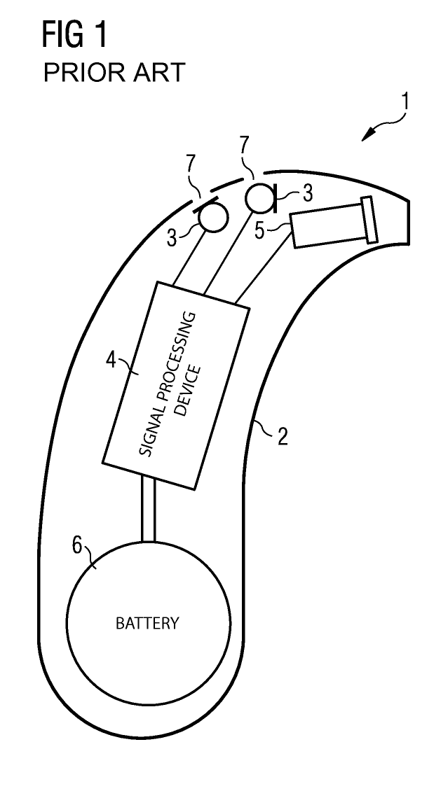

### DETAILED DESCRIPTION OF THE INVENTION

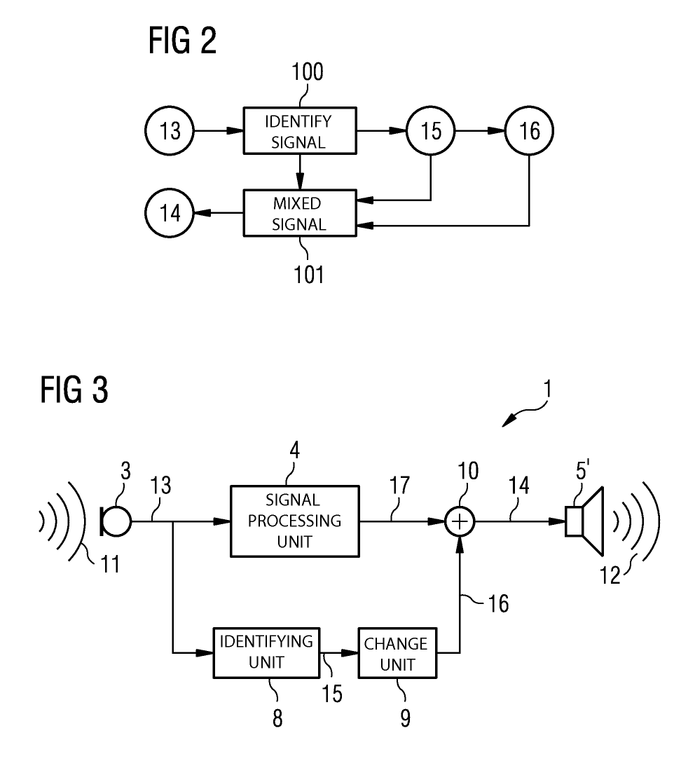

Referring now to the figures of the drawing in detail and first, particularly, to FIG. 2 thereof, there is shown a flow chart of a method for operating a hearing device 1 with a lengthening of fricatives. In step 100, a fricative signal 15 is identified in a microphone signal 13 of the hearing device. In a subsequent step 101, the fricative signal 15 or a changed fricative signal 16 are mixed with or added to an earpiece input signal 14 of the hearing device in such a way that a fricative of an ambient sound is reproduced in a temporally lengthened form by the hearing device in an output sound reproduced by an earpiece of the hearing device. The temporal lengthening can for example contain a reverberation of the fricative or an n-fold multiplication of the fricative, whereby n is ∈R and n>1.

FIG. 3 shows a block diagram of the hearing device 1 with a microphone 3, which records an ambient sound 11 and converts it into an electrical microphone signal 13. The microphone signal 13 is prepared and amplified in a signal processing unit 4 and outputs an electrical signal processing signal 17.

The microphone signal 13 is also investigated for predefinable fricatives in an identifying unit 8. The identified fricatives are emitted as a fricative signal 15 by the identifying unit 8. A search for the fricative “s”, for example, is performed.

With the aid of a change unit 9 the fricative signal 15 can be changed, for example amplified and temporally shifted. A changed fricative signal 16 thus formed is added to the signal processing signal 17 by an adder 10, via which an electrical earpiece input signal 14 is formed. In the earpiece input signal 14 the identified fricatives are lengthened by the temporally shifted addition. Thus, for example, the sound “s” persists for longer, and can thus be more clearly detected, which results in improved speech intelligibility.

The earpiece input signal 14 is received by an earpiece 5 and converted by this into an acoustic output signal 12. The acoustic output signal 12 is picked up by a wearer of the hearing device 1.

The identifying unit 8, the change unit 9 and the adder 10 can of course also be integrated into the signal processing unit 4.

1. A method for operating a hearing device having at least one microphone recording an ambient sound and an earpiece emitting an output sound, which comprises the step of:
reproducing a fricative of the ambient sound in a temporally lengthened form by the hearing device in the output sound.

2. The method according to claim 1, wherein a temporal lengthening includes a reverberation of the fricative.

3. The method according to claim 1, wherein a temporal lengthening includes an n-fold multiplication of the fricative, whereby n is ∈R and n>1.

4. The method according to claim 1, which further comprises:
identifying a fricative signal in a microphone signal; and
mixing an earpiece input signal with one of the fricative signal or a modified fricative signal.

5. A hearing device, comprising:
at least one microphone for recording an ambient sound;
an earpiece for emitting an output sound;
the hearing device identifying a fricative in a microphone signal emitted by said microphone and reproducing the fricative in the output sound in a temporally lengthened form.

6. The hearing device according to claim 5, wherein a temporal lengthening contains reverberation of the fricative.

7. The hearing device according to claim 5, wherein a temporal lengthening contains an n-fold multiplication of the fricative, whereby n∈R and n>1.

8. The hearing device according to claim 5, further comprising:
an identifying unit for identifying the fricative in the microphone signal;
a change unit for changing an identified fricative; and
an adder for adding a changed fricative to an earpiece input signal.
